(19) United States
(12) Patent Application Publication
(10) Pub. No.: US 2003/0101935 A1
(43) Pub. Date: Jun. 5, 2003

(54) Dose uniformity control for plasma doping systems

(76) Inventor: Steven R. Walther, Andover, MA (US)

Correspondence Address: Gary L. Loser, Esq., Varian Semiconductor Equipment Associates, Inc., 35 Dory Road, Gloucester, MA, 01930, US

(21) Appl. No.: 10/006,462

(22) Filed: Dec. 4, 2001

(51) Int. Cl. C23C 16/00

(52) U.S. Cl. 118/723 E

(57) ABSTRACT

Methods and apparatus are provided for controlling the dose uniformity of ions implanted into a workpiece in a plasma doping system. The plasma doping system includes a plasma doping chamber containing a platen for supporting a workpiece and an anode spaced from the platen. Dose uniformity may be improved by rotating the wafer to average azimuthal variations. Magnetic elements may be positioned around the plasma discharge region to control the radial density distribution of the plasma. The anode may have a spacing from the workpiece that varies over the area of the anode. The anode may include anode elements that are individually adjustable.

### FIELD OF THE INVENTION

This invention relates to plasma doping systems used for ion implantation of workpieces and, more particularly, to methods and apparatus for controlling the dose uniformity of ions implanted into the workpiece in plasma doping systems.

### BACKGROUND OF THE INVENTION

Ion implantation is a standard technique for introducing conductivity-altering impurities into semiconductor wafers. In a conventional beamline ion implantation system, a desired impurity material is ionized in an ion source, the ions are accelerated to form an ion beam of prescribed energy, and the ion beam is directed at the surface of the wafer. The energetic ions in the beam penetrate into the bulk of the semiconductor material and are embedded into the crystalline lattice of the semiconductor material to form a region of desired conductivity.

A well-known trend in the semiconductor industry is toward smaller, higher speed devices. In particular, both the lateral dimensions and the depths of features in semiconductor devices are decreasing. State of the art semiconductor devices require junction depths less than 1,000 Angstroms and may eventually require junction depths on the order of 200 Angstroms or less. The implanted depth of the dopant material is determined, at least in part, by the energy of the ions implanted into the semiconductor wafer. Beamline ion implanters are typically designed for efficient operation at relatively high implant energies and may not function efficiently at the low energies required for shallow junction implantation.

Plasma doping systems have been studied for forming shallow junctions in semiconductor wafers. In a plasma doping system, a semiconductor wafer is placed on a conductive platen, which functions as a cathode and is located in a plasma doping chamber. An ionizable process gas containing the desired dopant material is introduced into the chamber, and a voltage pulse is applied between the platen and an anode or the chamber walls, causing formation of a plasma having a plasma sheath in the vicinity of the wafer. The applied pulse causes ions in the plasma to cross the plasma sheath and to be implanted into the wafer. The depth of implantation is related to the voltage applied between the wafer and anode. Very low implant energies can be achieved. Plasma doping systems are described, for example, in U.S. Pat. No. 5,354,381, issued Oct. 11, 1994 to Sheng; U.S. Pat. No. 6,020,592, issued Feb. 1, 2000 to Liebert et al.; and U.S. Pat. No. 6,182,604, issued Feb. 6, 2001 to Goeckner et al. In the plasma doping system described above, the applied voltage pulse generates a plasma and accelerates positive ions from the plasma toward the wafer. In other types of plasma systems, known as plasma immersion systems, a continuous RF voltage is applied between the platen and the anode, thus producing a continuous plasma. At intervals, voltage pulses are applied between the platen and the anode, causing positive ions in the plasma to be accelerated toward the wafer.

Exacting requirements are placed on semiconductor fabrication processes involving ion implantation, with respect to the cumulative ion dose implanted into the wafer and spatial dose uniformity across the wafer surface. The implanted dose determines the electrical activity of the implanted region, whereas dose uniformity is required to ensure that all devices on the semiconductor wafer have operating characteristics within specified limits.

In a plasma doping system, the plasma which generates the ions is located at the surface of the wafer. Spatial dose uniformity depends on the uniformity of the plasma and on the electric fields in the vicinity of the wafer. However, the plasma may have spatial nonuniformities and may vary with time. Such plasma nonuniformities are likely to produce dose nonuniformity in the wafers being processed. A plasma doping system which utilizes a separately biased concentric structure surrounding the platen to improve dose uniformity is disclosed in U.S. Pat. No. 5,711,812, issued Jan. 27, 1998 to Chapek et al. Despite the improvement produced by this approach, dose uniformity remains an issue in plasma doping systems.

Accordingly, there is a need for improved plasma doping systems and techniques for uniformity control in plasma doping systems.

### SUMMARY OF THE INVENTION

According to a first aspect of the invention, plasma doping apparatus comprises a plasma doping chamber, a platen located in the plasma doping chamber for supporting a workpiece, an anode spaced from the platen in the plasma doping chamber, a process gas source coupled to the plasma doping chamber, a pulse source for applying pulses between the platen and the anode, and a mechanism for rotating the workpiece. A plasma containing ions of the process gas is produced in a plasma discharge region between the anode and platen. The pulses applied between the platen and the anode accelerate ions from the plasma into the workpiece. Rotation of the workpiece improves azimuthal dose uniformity.

In one embodiment, the workpiece comprises a semiconductor wafer and the mechanism rotates the platen such that the wafer is rotated about its center. Preferably, the pulse source has a pulse rate that is much greater than the rotation speed of the workpiece.

According to another aspect of the invention, plasma doping apparatus comprises a plasma doping chamber containing a platen for supporting a workpiece, a plasma source for generating a plasma in the plasma doping chamber and for accelerating ions from the plasma into the workpiece, and a drive mechanism for rotating the workpiece.

According to a further aspect of the invention, a method for a plasma doping comprises the steps of supporting a workpiece on a platen in a plasma doping chamber, generating a plasma and accelerating ions from the plasma into the workpiece, and rotating the workpiece.

According to another aspect of the invention, plasma doping apparatus comprises a plasma doping chamber, a platen in the plasma doping chamber for supporting a workpiece, an anode spaced from the platen in the plasma doping chamber, a process gas source coupled to the plasma doping chamber, and a pulse source for applying pulses between the platen and the anode. A plasma containing ions of the process gas is produced in a plasma discharge region between the anode and the platen. The pulses applied between the platen and the anode accelerate ions from the plasma into the workpiece. The anode has a spacing from the platen that varies over the area of the anode.

In one embodiment, the anode comprises two or more anode elements, such as annular anode elements, which are individually adjustable in spacing from the platen. The anode may comprise two or more anode elements and actuators for individually adjusting the spacing between respective anode elements and the platen to produce a desired dose uniformity in the workpiece.

According to a further aspect of the invention, a method for plasma doping comprises the steps of supporting a workpiece on a platen in a plasma doping chamber, positioning an anode in the plasma doping chamber in spaced relationship to the platen, the anode having two or more anode elements, adjusting the spacing between one or more of the anode elements and the platen, and generating a plasma between the anode and the platen and accelerating ions from the plasma into the workpiece.

According to a further aspect of the invention, plasma doping apparatus comprises a plasma doping chamber, a platen in the plasma doping chamber for supporting a workpiece, an anode spaced from the platen in the plasma doping chamber, a process gas source coupled to the plasma doping chamber, a pulse source for applying pulses between the platen and the anode, and a plurality of magnetic elements disposed around a plasma discharge region. A plasma containing ions of the process gas is produced in the plasma discharge region. The pulses applied between the platen and the anode accelerate ions from the plasma into the workpiece. The magnetic elements are configured for controlling the radial density distribution of the plasma in the plasma discharge region to thereby control the dose uniformity of the ions implanted into the workpiece.

In one embodiment, the magnetic elements are disposed on or near the anode. In another embodiment, the magnetic elements have a cylindrical arrangement around the plasma discharge region. In a further embodiment, the apparatus includes a hollow electrode surrounding the plasma discharge region, and the magnetic elements are disposed on or near the hollow electrode. Preferably, the magnetic elements have alternating polarities facing the plasma discharge region.

According to another aspect of the invention, a method for plasma doping comprises the steps of supporting a workpiece on a platen in a plasma doping chamber, generating a plasma in the plasma doping chamber and accelerating ions from the plasma into the workpiece, and magnetically controlling the radial density distribution of the plasma to thereby control the dose uniformity of the ions implanted into the workpiece.

### BRIEF DESCRIPTION OF THE DRAWINGS

For a better understanding of the present invention, reference is made to the accompanying drawings, which are incorporated herein by reference and in which:

FIG. 1 is a simplified schematic block diagram of a plasma doping system;

FIG. 2 is a partial schematic cross-sectional view of the plasma doping system, illustrating embodiments of the invention;

FIG. 3 is a top cross-sectional view of the plasma doping system, taken along the line 3-3 of FIG. 2;

FIG. 4 is a top cross-sectional view of the plasma doping system, taken along the line 4-4 of FIG. 2;

FIG. 5A is a partial schematic cross-sectional view of the plasma doping system, illustrating a first embodiment wherein magnetic elements are disposed on or near the anode;

FIG. 5B is a partial top view of the embodiment shown FIG. 5A;

FIG. 6 is a partial schematic cross-sectional view of the plasma doping system, illustrating a second embodiment wherein magnetic elements are disposed on or near the anode; and

FIG. 7 is a graph of magnetic field as a function of radius in the plasma discharge region, illustrating an example of a radial magnetic field profile.

### DETAILED DESCRIPTION

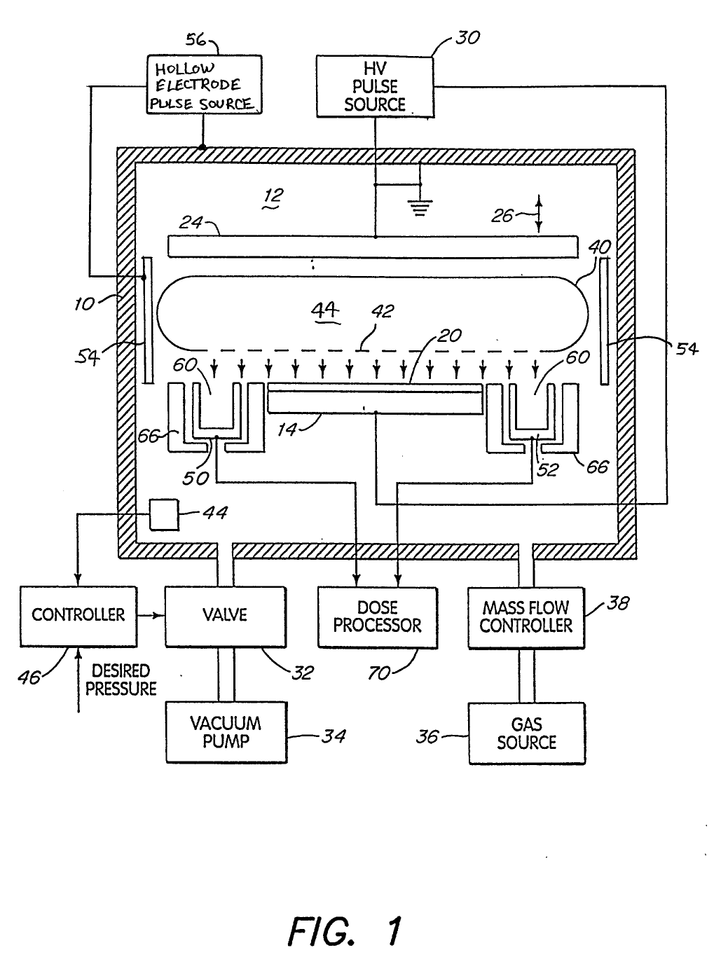

An example of a plasma doping system suitable for implementation of the present invention is shown schematically in FIG. 1. A plasma doping chamber 10 defines an enclosed volume 12. A platen 14 positioned within chamber 10 provides a surface for holding a workpiece, such as a semiconductor wafer 20. The wafer 20 may, for example, be clamped at its periphery to a flat surface of platen 14. In one embodiment, the platen has an electrically conductive surface for supporting wafer 20. In another embodiment, the platen includes conductive pins (not shown) for connection to wafer 20.

An anode 24 is positioned within chamber 10 in spaced relation to platen 14. Anode 24 may be movable in a direction, indicated by arrow 26, perpendicular to platen 14. The anode is typically connected to electrically conductive walls of chamber 10, both of which may be connected to ground. In another embodiment, platen 14 is connected to ground, and anode 24 is pulsed, as described below.

The wafer 20 (via platen 14) and the anode 24 are connected to a high voltage pulse source 30, so that wafer 20 functions as a cathode. The pulse source 30 typically provides pulses in a range of about 100 to 5000 volts in amplitude, about 1 to 50 microseconds in duration and a pulse repetition rate of about 100 Hz to 2 kHz. It will be understood that these pulse parameter values are given by way of example only and that other values may be utilized within the scope of the invention.

The enclosed volume 12 of chamber 10 is coupled through a controllable valve 32 to a vacuum pump 34. A process gas source 36 is coupled through a mass flow controller 38 to chamber 10. A pressure sensor 44 located within chamber 10 provides a signal indicative of chamber pressure to a controller 46. The controller 46 compares the sensed chamber pressure with a desired pressure input and provides a control signal to valve 32. The control signal controls valve 32 so as to minimize the difference between the chamber pressure and the desired pressure. Vacuum pump 34, valve 32, pressure sensor 44 and controller 46 constitute a closed loop pressure control system. The pressure is typically controlled in a range of about 1 millitorr to about 500 millitorr, but is not limited to this range. Gas source 36 supplies an ionizable gas containing a desired dopant for implantation into the workpiece. Examples of ionizable gas include BF₃, N₂, Ar, PH₃, AsH₃ and B₂H₆. Mass flow controller 38 regulates the rate at which gas is supplied to chamber 10. The configuration shown in FIG. 1 provides a continuous flow of processed gas at a constant gas flow rate and constant pressure. The pressure and gas flow rate are preferably regulated to provide repeatable results.

The plasma doping system may include a hollow cathode 54 connected to a hollow cathode pulse source 56. In one embodiment, the hollow cathode 54 comprises a conductive hollow cylinder that surrounds the space between anode 24 and platen 14. The hollow cathode may be utilized in applications which require very low ion energies. In particular, hollow cathode pulse source 56 provides a pulse voltage that is sufficient to form a plasma within chamber 12, and pulse source 30 establishes a desired implant voltage. Additional details regarding the use of a hollow cathode are provided in the aforementioned U.S. Pat. No. 6,182,604, which is hereby incorporated by reference.

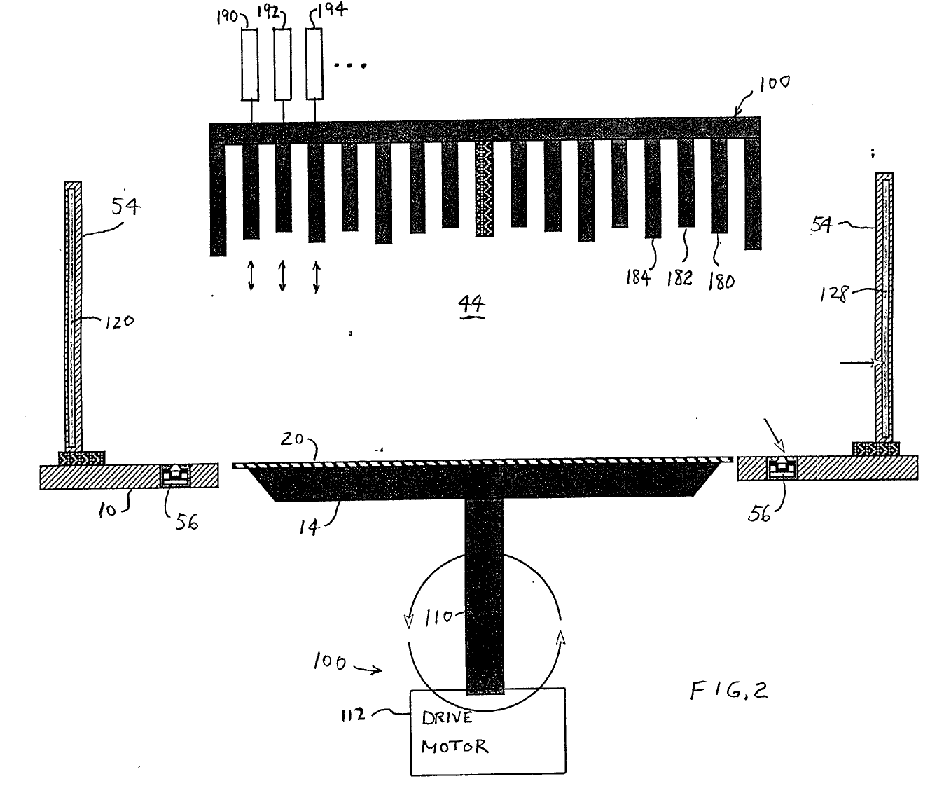

One or more Faraday cups may be positioned adjacent to platen 14 for measuring the ion dose implanted into wafer 20. In the embodiment of FIG. 1, Faraday cups 50, 52, etc. are equally spaced around the periphery of wafer 20. Each Faraday cup comprises a conductive enclosure having an entrance 60 facing plasma 40. Each Faraday cup is preferably positioned as close as is practical to wafer 20 and intercepts a sample of the positive ion accelerated from plasma 40 toward platen 14. In another embodiment, an annular Faraday cup 56 (see FIG. 2) is positioned around wafer 20 and platen 14.

The Faraday cups are electrically connected to a dose processor 70 or other dose monitoring circuit. Positive ions entering each Faraday cup through entrance 60 produce in the electrical circuit connected to the Faraday cup a current that is representative of ion current. The dose processor 70 may process the electrical current to determine ion dose.

As described in the aforementioned U.S. Pat. No. 5,711,812, the plasma doping system may include a guard ring 66 that surrounds platen 14. The guard ring 66 may be biased to improve the uniformity of implanted ion distribution near the edge of wafer 20. The Faraday cups 50, 52 may be positioned within guard ring 66 near the periphery of wafer 20 and platen 14.

In operation, wafer 28 is positioned on platen 14. The pressure control system, mass flow controller 38 and gas source 36 produce the desired pressure and gas flow rate within chamber 10. By way of example, the chamber 10 may operate with BF₃ gas at a pressure of 10 millitorr. The pulse source 30 applies a series of high voltage pulses to wafer 20, causing formation of a plasma 40 in a plasma discharge region 44 between wafer 20 and anode 24. As known in the art, plasma 40 contains positive ions of the ionizable gas from gas source 36. Plasma 40 includes a plasma sheath in the vicinity, typically at the surface, of wafer 20. The electric field that is present between anode 24 and platen 14 during the high voltage pulse accelerates positive ions from plasma 40 across plasma sheath 42 toward platen 14. The accelerated ions are implanted into wafer 20 to form regions of impurity material. The pulse voltage is selected to implant the positive ions to a desired depth in wafer 20. The number of pulses and the pulse duration are selected to provide a desired dose of impurity material in wafer 20. The current per pulse is a function of pulse voltage, gas pressure and species and any variable position of the electrodes. For example, the cathode-to-anode spacing may be adjusted for different voltages.

Ion dose uniformity over the surface of wafer 20 depends on the uniformity of plasma 40 and on the electric fields in the vicinity of wafer 20. However, plasma 40 may have spatial nonuniformities and may vary with time. Accordingly, there is a need for techniques for dose uniformity control in plasma doping systems.

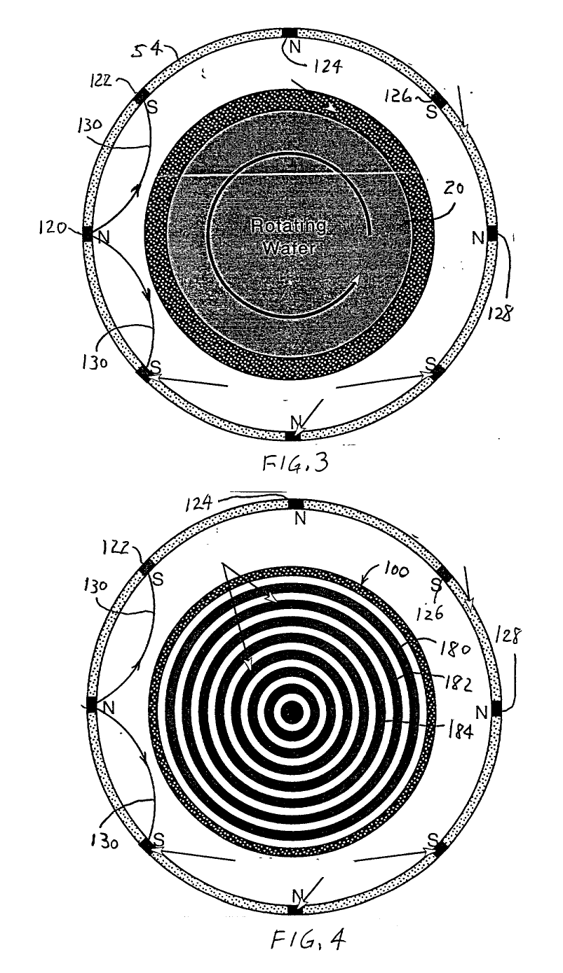

Embodiments of the invention are described with reference to FIGS. 2-4, 5A, 5B, 6 and 7, where like elements have the same reference numerals. A partial cross-sectional view of an embodiment of a plasma doping system is shown in FIG. 2. The features illustrated in FIGS. 2-6 may be utilized in a plasma doping system of the type shown in FIG. 1 and described above, or in any other plasma doping system. The features may be used separately or in any combination to improve ion dose uniformity.

As shown in FIG. 2, the plasma doping system may include a drive mechanism 100 for rotating wafer 20 during plasma doping. Drive mechanism 100 may include a drive motor 112 and a shaft 110 connected between platen 14 and drive motor 112. Preferably, drive motor 112 is located externally of chamber 10. During plasma doping, drive motor 112 is energized, causing platen 14 and wafer 20 to rotate in the plane of wafer 20. Preferably, the center of rotation is at or near the center of wafer 20. The wafer 20 is preferably rotated at a speed in a range of about 10 to 600 rpm. In one embodiment, wafer 20 is rotated at a speed of a few rotations per second. The rotation speed of wafer 20 is preferably selected such that the pulse rate of pulse source 30 is much greater than the rotation speed. In addition, the rotation of wafer 20 should not be synchronized with the operation of pulse source 30. By rotating wafer 20 during plasma doping, azimuthal uniformity variations are averaged over the wafer surface, thereby increasing dose uniformity.

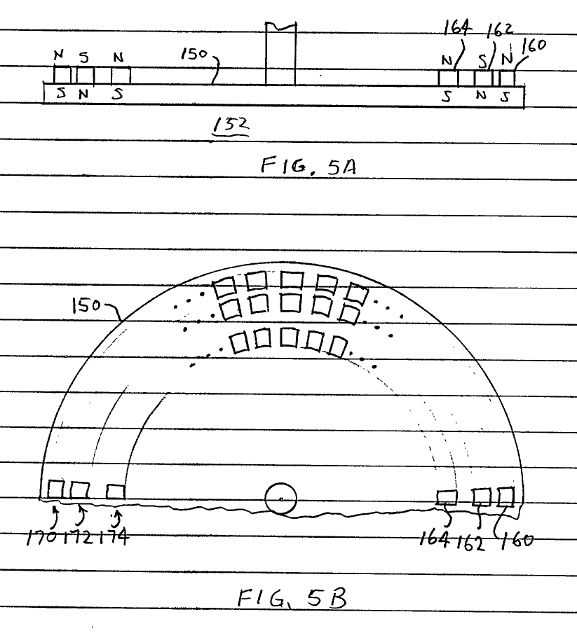

According to another feature of the invention, the plasma doping system may be provided with magnetic elements disposed around the plasma discharge region to control the radial density distribution of the plasma in plasma discharge region 44 and to thereby improve the dose uniformity of ions implanted into wafer 20. A cross-sectional view of an anode 150 is shown in FIG. 5A, and a top view of anode 150 is shown in FIG. 5B. Anode 150 may correspond to anode 24 shown in FIG. 1 and described above. Magnetic elements 160, 162, 164, etc. are mounted on a surface of anode 150 opposite a plasma discharge region 152. Magnetic elements 160, 162, 164, etc. may be permanent magnets mounted such that alternating poles face discharge region 152. In the embodiment of FIGS. 5A and 5B, magnetic elements 160, 162, 164, etc. are arranged in a series of concentric annular rings 170, 172 and 174. This configuration produces radially varying magnetic fields in a region near anode 150 that changes the radial density profile of the plasma and improves dose uniformity over a relatively broad range of process parameters. Such process parameters may include gas pressure, gas species, wafer bias and anode-to-cathode spacing.

A second embodiment of an anode having magnetic elements for controlling the radial density distribution of the plasma in the plasma discharge region is shown in FIG. 6. Magnetic elements 180, 182, 184, etc. are mounted on an anode 190. In the embodiment of FIG. 6, magnetic elements 180, 182, 184, etc. are elongated and are radially aligned to form a spoke configuration. Magnetic elements 180, 182, 184, etc. produce radially varying magnetic fields that change the radial density profile of the plasma and improve the dose uniformity of ions implanted into wafer 20.

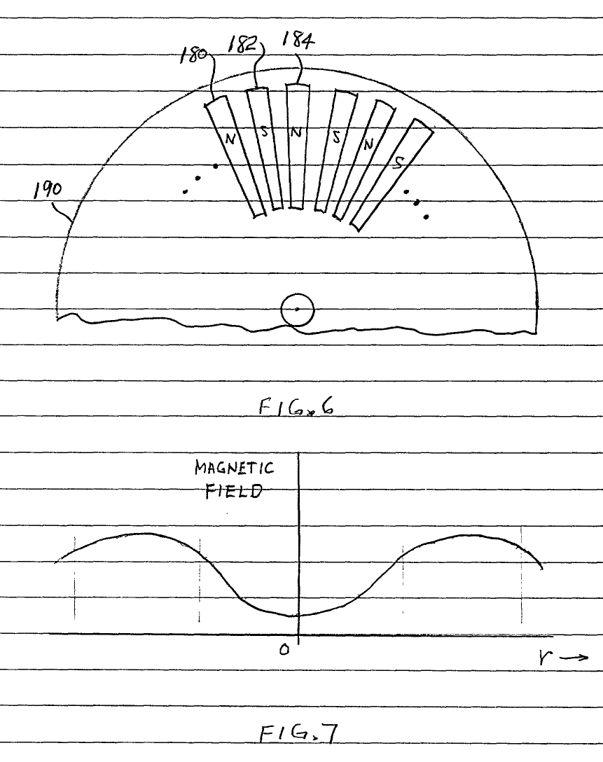

It will be understood that a variety of magnetic element configurations may be utilized and that the embodiments of FIGS. 5A, 5B and 6 are given by way of example only. The magnetic elements are utilized to control the radial density distribution of the plasma in the plasma discharge region. A goal of controlling the radial density distribution of the plasma is to improve the dose uniformity of ions implanted into wafer 20. A magnetic field is provided adjacent to portions of the plasma discharge region where an increase in plasma density is desired. Referring to FIG. 7, an example of a graph of magnetic field as a function of radius in the plasma discharge region is shown. In the illustrated example, the magnetic field is greater in an outer portion of the plasma discharge region and is less near the center, thereby producing an increase in plasma density in the outer portion of the plasma discharge region. A magnetic field distribution as shown in FIG. 7 corresponds generally to the configurations shown in FIGS. 5A, 5B and 6, where magnetic elements are provided adjacent to an outer portion of the plasma discharge region. It will be understood that a variety of magnetic field distributions can be utilized within the scope of the invention. For example, the magnetic field may be greater near the center of the plasma discharge region and less in an outer portion in cases where an increase in plasma density near the center is desired.

A variety of different magnetic element configurations can be utilized to provide a desired radial density distribution of the plasma in the plasma discharge region. As described above in connection with FIGS. 5A and 5B, annular rings of magnetic elements may be utilized. As described above in connection with FIG. 6, radially-oriented magnetic elements may be utilized. The strengths of the magnetic elements may be the same or different, depending on the desired radial magnetic field profile. Furthermore, the positions of the magnetic elements may be selected to provide a desired radial magnetic field profile. In addition, the radial and azimuthal dimensions of the magnetic elements and the radial and azimuthal spacing between magnetic elements may be selected to provide a desired radial magnetic field profile. The magnetic elements preferably produce magnetic fields in a range of about 20-5000 gauss. In one embodiment, the magnetic elements produce magnetic fields of about 500 gauss.

In the embodiments of FIGS. 5A, 5B and 6, the magnetic elements are positioned on a surface of the anode opposite the plasma discharge region. However, the magnetic elements can have any desired positions around the plasma discharge region to control the radial density distribution of the plasma.

In another embodiment illustrated in FIGS. 2-4, magnetic elements 120, 122, 124, 126, 128, etc. are spaced apart around discharge region 44. Because the plasma doping system of FIGS. 2-4 has a cylindrical geometry, magnetic elements 120, 122, 124, 126, 128, etc. may have a circular arrangement. In the embodiment of FIGS. 2-4, magnetic elements 120, 122, 124, 126, 128, etc. comprise elongated permanent magnets affixed to hollow cathode 54 and have alternating poles facing discharge region 44. Magnetic elements 120, 122, 124, 126, 128, etc. produce cusp magnetic fields 130 in an annular region outside the radius of wafer 20. The magnetic elements may have lengths that span the plasma discharge region 44. The number of magnetic elements and the strength of the magnets are selected to produce cusp magnetic fields 130 control the radial density distribution of the plasma in plasma discharge region 44.

Preferably, cusp magnetic fields 130 are located in an annular region around plasma discharge region 44 and do not extend substantially into discharge region 44. The cusp magnetic fields 130 which control the radial density distribution of the plasma between anode 100 and wafer 20, with sufficient overlap of the plasma at the edges of the wafer 20 to ensure edge uniformity. As a result, the spatial distribution of the plasma is controlled, and radial dose uniformity is improved over a broad range of plasma process parameters.

According to a further feature of the invention, the anode may have a spacing from the cathode that varies over the area of the anode. The anode may have a fixed configuration, but preferably has two or more adjustable anode elements to accommodate different operating conditions and different applications. The spacing between the anode elements and the cathode may be adjusted to achieve desired plasma characteristics and a desired dose uniformity.

In the embodiment of FIGS. 2-4, an anode 100 is constructed with anode elements in the form of vertically adjustable annular rings 180, 182, 184, etc. Annular rings 180, 182, 184, etc. may be adjusted to provide a variable anode-cathode spacing as a function of radius from the wafer center. This has the effect of varying the plasma density radially. The annular rings 180, 182, 184, etc. can be adjusted empirically based on measured wafer uniformity or can be adjusted using an in situ implant uniformity measurement to reduce radial implant dose variation. The annular rings 180, 182, 184, etc. can be individually adjusted. The adjustment can be manual, or the annular rings 180, 182, 184, etc. can be connected to individually controllable actuators 190, 192, 194, respectively.

In other embodiments, the anode can be configured as a grid of individually controllable anode elements or with a plurality of arbitrarily-shaped anode elements, each of which is individually controllable. In each case, the spacing between the anode and the wafer can vary over the area of the anode to achieve a desired dose uniformity. In yet another embodiment, the anode has a fixed configuration which provides a spacing between the anode and the wafer that varies over the area of the anode. This configuration is less preferred, because the plasma spatial distribution is likely to change for different plasma doping parameters, such as ion species, process gas pressure and the like.

The above described features for improving plasma doping uniformity, including rotation of the wafer, the use of magnetic elements to control the plasma spatial distribution and the use of an anode having a spacing from the wafer that varies over the area of the anode, may be used separately or in any combination to improve plasma doping uniformity.

Other plasma doping architectures may be utilized within the scope of the invention. For example, the plasma may be pulsed or continuous. The plasma may be generated by a DC voltage, an RF voltage or a microwave voltage, each of which may be pulsed or continuous. Different process gas pressures may be utilized.

It should be understood that various changes and modifications of the embodiments shown in the drawings described in the specification may be made within the spirit and scope of the present invention. Accordingly, it is intended that all matter contained in the above description and shown in the accompanying drawings be interpreted in an illustrative and not in a limiting sense. The invention is limited only as defined in the following claims and the equivalents thereto.

What is claimed is:

1. Plasma doping apparatus comprising:
a plasma doping chamber;
a platen located in said plasma doping chamber for supporting a workpiece;
an anode spaced from said platen in said plasma doping chamber;
a process gas source coupled to said plasma doping chamber, wherein a plasma containing ions of the process gas is produced in a plasma discharge region between said anode and said platen;
a pulse source for applying pulses between said platen and said anode for accelerating ions from the plasma into the workpiece; and
a mechanism for rotating the workpiece.

2. Plasma doping apparatus as defined in claim 1, wherein said platen is configured for supporting a semiconductor wafer and wherein said mechanism is configured for rotating said platen such that the semiconductor wafer rotates about its center.

3. Plasma doping apparatus as defined in claim 1, wherein said pulse source has a pulse rate that is much greater than a rotation speed of the workpiece.

4. Plasma doping apparatus as defined in claim 1, wherein said mechanism is configured for rotating the workpiece at a speed in a range of about 10 to 600 rpm.

5. Plasma doping apparatus comprising;
a plasma doping chamber containing a platen for supporting a workpiece;
a plasma source for generating a plasma in the plasma doping chamber and for accelerating ions from the plasma into the workpiece; and
a drive mechanism for rotating the workpiece.

6. A method for plasma doping, comprising the steps of:
supporting a workpiece on a platen in a plasma doping chamber;
generating a plasma and accelerating ions from the plasma into the workpiece; and
rotating the workpiece.

7. A method as defined in claim 6, wherein the workpiece comprises a semiconductor wafer and wherein the step of rotating the workpiece comprises rotating the platen such that the semiconductor wafer rotates about its center.

8. A method as defined in claim 6, further comprising the step of applying pulses having a pulse rate between the platen and an anode in the plasma doping chamber, wherein the pulse rate is much greater than a rotation rate of the workpiece.

9. A method as defined in claim 6, wherein the workpiece is rotated at a speed in the range of about 10 to 600 rpm.

10. Plasma doping apparatus comprising:
a plasma doping chamber;
a platen in said plasma doping chamber for supporting a workpiece;
an anode spaced from said platen in said plasma doping chamber, said anode having a spacing from said platen that varies over the area of said anode;
a process gas source coupled to said plasma doping chamber, wherein a plasma containing ions of the process gas is produced in a plasma discharge region between said anode and said platen; and
a pulse source for applying pulses between said platen and said anode for accelerating ions from the plasma into the workpiece.

11. Plasma doping apparatus as defined in claim 10, wherein said anode comprises two or more anode elements and actuators for individually adjusting the spacing between respective anode elements and the platen to produce a desired dose uniformity in the workpiece.

12. Plasma doping apparatus as defined in claim 11, wherein said two or more anode elements comprise annular rings.

13. Plasma doping apparatus as defined in claim 10, wherein the workpiece comprises a semiconductor wafer and wherein the spacing between said anode and said platen is adjustable as a function of radius relative to the center of the semiconductor wafer.

14. Plasma doping apparatus comprising:
a plasma doping chamber containing a platen for supporting a workpiece;
an anode spaced from said platen in said plasma doping chamber, said anode comprising two or more anode elements and actuators for individually adjusting the spacing between said two or more anode elements and the platen;
a process gas source coupled to said plasma doping chamber, wherein a plasma containing ions of the process gas is produced in a plasma discharge region between said anode and said platen; and
a pulse source for applying pulses between said platen and said anode for accelerating ions from the plasma into the workpiece.

15. A method for plasma doping, comprising the steps of:
supporting a workpiece on a platen in a plasma doping chamber;
positioning an anode in the plasma doping chamber in spaced relationship to the platen, said anode having two or more anode elements;
adjusting the spacing between one or more of said anode elements and the platen; and
generating a plasma between the anode and the platen and accelerating ions from the plasma into the workpiece.

16. A method as defined in claim 15, wherein the workpiece comprises a semiconductor wafer and wherein the step of adjusting the spacing comprises adjusting the spacing of said anode elements as a function of radius relative to the center of the semiconductor wafer.

17. A method as defined in claim 15, wherein the anode elements comprise annular rings and wherein the step of adjusting the spacing comprises adjusting the spacing between one or more of the annular rings and the platen.

18. Plasma doping apparatus comprising:
a plasma doping chamber having a cylindrical geometry;
a platen in said plasma doping chamber for supporting a workpiece;
an anode spaced from said platen in said plasma doping chamber;
a process gas source coupled to said plasma doping chamber, wherein a plasma containing ions of the process gas is produced in a plasma discharge region between said anode and said platen;
a pulse source for applying pulses between said platen and said anode for accelerating ions from the plasma into the workpiece; and
a plurality of magnetic elements disposed around the plasma discharge region for controlling the radial density distribution of the plasma in the plasma discharge region to thereby control the dose uniformity of the ions implanted into the workpiece.

19. Plasma doping apparatus as defined in claim 18, wherein said magnetic elements are disposed on or near said anode.

20. Plasma doping apparatus as defined in claim 19, wherein said magnetic elements are arranged in one or more annular rings.

21. Plasma doping apparatus as defined in claim 19, wherein said magnetic elements are radially aligned to form a spoke configuration.

22. Plasma doping apparatus as defined in claim 18, wherein said magnetic elements have alternating polarities facing the plasma discharge region.

23. Plasma doping apparatus as defined in claim 18, wherein said magnetic elements are configured to increase the plasma density in an outer portion of the plasma discharge region.

24. Plasma doping apparatus as defined in claim 18, wherein said magnetic elements are arranged in a cylindrical array around the plasma discharge region.

25. Plasma doping apparatus as defined in claim 24, wherein said magnetic elements comprise axial magnetic elements having alternating polarities facing the plasma discharge region.

26. Plasma doping apparatus as defined in claim 18, further comprising a hollow electrode surrounding the plasma discharge region, wherein said magnetic elements are disposed on or near said hollow electrode.

27. Plasma doping apparatus as defined in claim 18, wherein said magnetic elements produce cusp magnetic fields in a region adjacent to the plasma discharge region.

28. A method for plasma doping, comprising the steps of:
supporting a workpiece on a platen in a plasma doping chamber;
generating a plasma in the plasma doping chamber and accelerating ions from the plasma into the workpiece; and
magnetically controlling the radial density distribution of the plasma to thereby control the dose uniformity of the ions implanted into the workpiece.

29. A method as defined in claim 28, wherein the step of magnetically controlling the radial density distribution of the plasma comprises controlling the radial density distribution with magnetic elements that produce a prescribed radial magnetic field profile

30. A method as defined in claim 28, wherein the step of magnetically controlling the radial density distribution of the plasma comprises controlling the radial density distribution with one or more annular rings of magnetic elements disposed adjacent to the plasma.

31. A method as defined in claim 28, wherein the step of magnetically controlling the radial density distribution of the plasma comprises controlling the radial density distribution with radially aligned magnetic elements which form a spoke configuration.

32. A method as defined in claim 28, wherein the step of magnetically controlling the radial density distribution of the plasma comprises increasing the plasma density in an outer portion of the plasma doping chamber.

33. A method as defined in claim 28, wherein the step of magnetically controlling the radial density distribution of the plasma comprises increasing the plasma density in a specified portion of the plasma doping chamber by providing magnetic fields adjacent to the specified portion of the plasma doping chamber.
